(19) United States
(12) Patent Application Publication
(10) Pub. No.: US 2026/0173904 A1
(43) Pub. Date: Jun. 18, 2026

(54) SEMICONDUCTOR DEVICE AND METHOD OF FABRICATING THE SAME

(71) Applicant: Samsung Electronics Co., Ltd., Suwon-si (KR)

(72) Inventors: JINHEE HONG, Suwon-si (KR); MINKYEONG PARK, Suwon-si (KR)

(21) Appl. No.: 19/250,552

(22) Filed: Jun. 26, 2025

(30) Foreign Application Priority Data
Dec. 13, 2024 (KR) 10-2024-0186430

(51) Int. Cl. H01L 23/00; H01L 23/538; H01L 25/065; H01L 25/18; H10B 80/00; H10D 80/30

(52) U.S. Cl. CPC H10W 70/60; H10W 70/611; H10W 90/00; H10B 80/00; H10D 80/30; H10W 72/5473; H10W 72/851; H10W 90/20; H10W 90/24; H10W 90/732; H10W 90/734; H10W 90/752; H10W 90/754

(57) ABSTRACT

A semiconductor package may include a substrate, first and second channel pads, a first chip that includes a first chip pad and is on the substrate, a second chip that includes a second chip pad and is on the first chip, a third chip that includes a third chip pad and a first power-ground pad and is on the second chip, a first channel wire connecting the first chip pad to the first channel pad, a first connection wire connecting the first chip pad to the second chip pad, a first power-ground wire connecting the second chip pad to the first power-ground pad, and a second channel wire connecting the third chip pad to the second channel pad. The first power-ground pad may be closer to the second chip pad than to the third chip pad. The first, second, and third chips may be electrically connected to each other.

### CROSS-REFERENCE TO RELATED APPLICATIONS

This U.S. non-provisional patent application claims priority under 35 U.S.C. § 119 to Korean Patent Application No. 10-2024-0186430, filed on Dec. 13, 2024, in the Korean Intellectual Property Office, the entire contents of which are hereby incorporated by reference

### TECHNICAL FIELD

The present disclosure relates to a semiconductor package, and in particular, to a semiconductor package with improved electrical characteristics.

### BACKGROUND

A semiconductor device is configured to employ an integrated circuit chip as a part of an electronic product. The semiconductor device may be a semiconductor package. In general, the semiconductor package may include a printed circuit board (PCB) and a semiconductor chip, which is mounted on the PCB and is electrically connected to the PCB by bonding wires or bumps.

With the development of the electronics industry, many studies are being conducted to improve the reliability of the semiconductor package and to reduce a size of the semiconductor package. In order to achieve this, it may be desirable to develop packaging technologies of reducing a size of each component and technologies of integrating a plurality of individual components in a single package. In particular, for a semiconductor package used to process high frequency signals, it may be desirable not only to reduce the size of the semiconductor package but also to improve the electrical characteristics of the semiconductor package.

### SUMMARY

Some embodiments of the present disclosure provides a semiconductor package with improved electrical characteristics.

According to some embodiments of the present disclosure, a semiconductor package may include a substrate that includes a first channel pad and a second channel pad that are spaced apart from each other in a first direction and a first side surface and a second side surface that are opposite to each other, a first semiconductor chip that is on the substrate and includes a first chip pad, a second semiconductor chip that is on the first semiconductor chip and includes a second chip pad, a third semiconductor chip that is on the second semiconductor chip and includes a third chip pad and a first power-ground pad that are spaced apart from each other in the first direction, a first channel wire that electrically connects the first chip pad to the first channel pad, a first connection wire that electrically connects the first chip pad to the second chip pad, a first power-ground wire that electrically connects the second chip pad to the first power-ground pad, and a second channel wire that electrically connects the third chip pad to the second channel pad, where the first power-ground pad is closer to the second chip pad than to the third chip pad in the first direction and is configured to receive one of a power signal or a ground signal, where the second semiconductor chip is electrically connected to the first channel pad, where the third semiconductor chip is electrically connected to the second channel pad.

According to some embodiments of the present disclosure, a semiconductor package may include a substrate including a first side surface and a second side surface that are opposite to each other, the substrate including a first channel pad adjacent to the first side surface, a second channel pad adjacent to the second side surface, and a third channel pad adjacent to the first channel pad, a first chip structure on the substrate, a second chip structure on the first chip structure including a second set of chip pads adjacent to the first side surface, and a third chip structure that is on the second chip structure and includes a third set of chip pads that is closer to the second side surface than the second set of chip pads in a first direction that is parallel to an upper surface of the substrate, where the first chip structure is electrically connected to the first channel pad, the second chip structure is electrically connected to the second channel pad, the second chip structure includes a first power-ground wire adjacent to the first side surface, the third chip structure includes a second power-ground wire adjacent to the second side surface, the first power-ground wire electrically connects the first chip structure to the second chip structure, and the second power-ground wire electrically connects the second chip structure to the third chip structure.

According to some embodiments of the present disclosure, a semiconductor package may include a substrate including a first side surface and a second side surface that are opposite to each other, the substrate including a first channel pad in a first direction that is parallel to an upper surface of the substrate, a second channel pad spaced apart from the first channel pad in the first direction, a third channel pad adjacent to the first channel pad, and a fourth channel pad adjacent to the second channel pad, a first semiconductor chip that is on the substrate and includes a first chip pad, a second semiconductor chip that is on the first semiconductor chip and includes a second chip pad, a third semiconductor chip that is on the second semiconductor chip and includes a third chip pad and a first power-ground pad spaced apart from each other in the first direction, a fourth semiconductor chip that is on the third semiconductor chip and includes a fourth chip pad, a fifth semiconductor chip that is on the fourth semiconductor chip and includes a fifth chip pad and a second power-ground pad spaced apart from each other in the first direction, a first channel wire electrically connecting the first chip pad to the first channel pad, a connection wire electrically connecting the first chip pad to the second chip pad, a power-ground wire electrically connecting the second chip pad to the first power-ground pad and electrically connecting the fourth chip pad to the second power-ground pad, a second channel wire electrically connecting the third chip pad to the second channel pad, and a third channel wire electrically connecting the fifth chip pad to the third channel pad, where the second semiconductor chip is electrically connected to the first channel pad, where the third semiconductor chip is electrically connected to the second channel pad, and where the second semiconductor chip and the third semiconductor chip are electrically connected to each other through the power-ground wire.

### BRIEF DESCRIPTION OF THE DRAWINGS

FIG. 1 is a plan view illustrating a semiconductor device according to some embodiments of the present disclosure.

FIG. 2 is a sectional view taken along a line A-A′ of FIG. 1 illustrating a semiconductor device according to some embodiments of the present disclosure.

FIG. 3 is a plan view illustrating a semiconductor device according to some embodiments of the present disclosure.

FIG. 4 is a sectional view taken along a line A-A′ of FIG. 3 illustrating a semiconductor device according to some embodiments of the present disclosure.

FIG. 5 is a plan view illustrating a semiconductor device according to some embodiments of the present disclosure.

FIG. 6 is a sectional view taken along a line A-A′ of FIG. 5 illustrating a semiconductor device according to some embodiments of the present disclosure.

FIG. 7 is a plan view illustrating a semiconductor device according to some embodiments of the present disclosure.

FIG. 8 is a sectional view taken along a line A-A′ of FIG. 7 illustrating a semiconductor device according to some embodiments of the present disclosure.

### DETAILED DESCRIPTION

Example embodiments of the inventive concepts will now be described more fully with reference to the accompanying drawings, in which example embodiments are shown.

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The terms “first,” “second,” etc. may be used herein to merely distinguish one component, element, etc., from another.

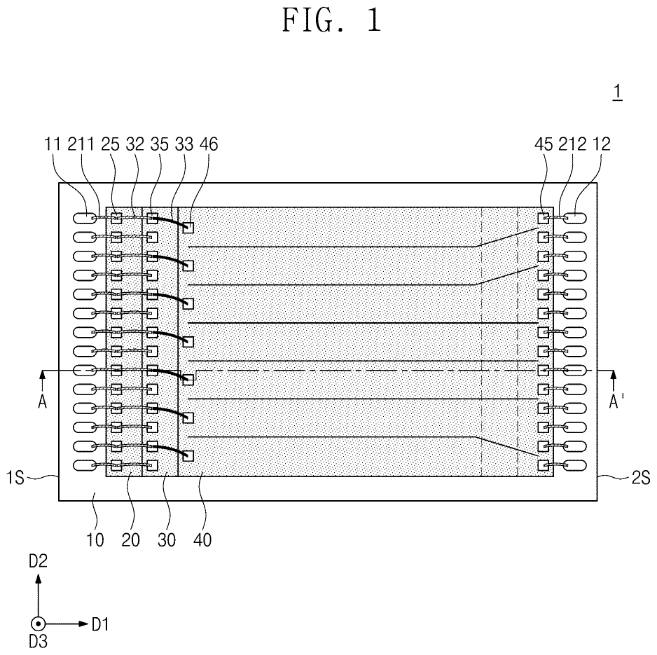

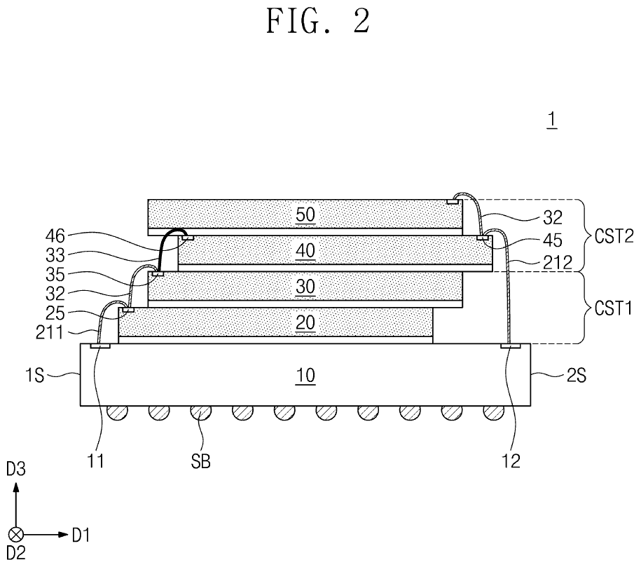

FIG. 1 is a plan view illustrating a semiconductor device according to some embodiments of the present disclosure. FIG. 2 is a sectional view taken along a line A-A′ of FIG. 1 to illustrate a semiconductor device according to some embodiments of the present disclosure.

Referring to FIG. 1, a semiconductor device 1 according to some embodiments of the present disclosure may include a substrate 10 having a first side surface 1S and a second side surface 2S, which are opposite to each other. The substrate 10 may be a plate-shaped structure that extends in a first direction D1 and a second direction D2, which are not parallel to each other. A third direction D3 may be defined to be perpendicular to a top surface of the substrate 10. The first and second side surfaces 1S and 2S may extend in the third direction D3.

The substrate 10 may include a plurality of first channel pads 11, which are adjacent to the first side surface 1S and are arranged in the second direction D2. The substrate 10 may include a plurality of second channel pads 12, which are adjacent to the second side surface 2S and are arranged in the second direction D2.

Solder balls SB may be provided below the substrate 10. The solder balls SB may include a solder material. The solder balls SB may connect the substrate 10 to outer terminals.

A plurality of chip structures CST1 and CST2, which are stacked in the third direction D3, may be provided on the substrate 10. A first chip structure CST1 may be disposed on the substrate 10. A second chip structure CST2 may be disposed on the first chip structure CST1.

The first chip structure CST1 may include a first semiconductor chip 20 in contact with the substrate 10 and a second semiconductor chip 30 on the first semiconductor chip 20. The first chip structure CST1 may include a first channel wire 211, which is provided to connect the first semiconductor chip 20 to the first channel pad 11, and a connection wire 32, which is provided to connect the first semiconductor chip 20 to the second semiconductor chip 30.

The first semiconductor chip 20 may include a first chip pad 25, which is disposed adjacent to the first side surface 1S. In some embodiments, a plurality of first chip pads 25 may be arranged in the second direction D2. The first chip pads 25 may be arranged in the same number as the first channel pads 11. The first semiconductor chip 20 may have an opened pad, which is adjacent to the second side surface 2S.

The second semiconductor chip 30 may include second chip pads 35, which are disposed adjacent to the first side surface 1S. In some embodiments, a plurality of second chip pads 35 may be arranged in the second direction D2.

The first chip pads 25 and the first channel pad 11 may be connected to each other using the first channel wire 211. The first chip pads 25 and the second chip pads 35 may be connected to each other using the connection wire 32.

The second chip structure CST2 may include a third semiconductor chip 40 in contact with the second semiconductor chip 30 and a fourth semiconductor chip 50 on the third semiconductor chip 40. The second chip structure CST2 may include a second channel wire 212 connecting the third semiconductor chip 40 to the second channel pad 12, the connection wire 32 connecting the third semiconductor chip 40 to the fourth semiconductor chip 50, and a power-ground wire 33 connecting the second semiconductor chip 30 to the third semiconductor chip 40.

The third semiconductor chip 40 may include first power-ground pads 46, which are disposed adjacent to the first side surface 1S, and third chip pads 45, which are disposed adjacent to the second side surface 2S. The first power-ground pads 46 and the third chip pads 45 may be spaced apart from each other in the first direction D1. The first power-ground pads 46 may be arranged in the second direction D2, and the third chip pads 45 may be arranged in the second direction D2. The number of the first power-ground pads 46 may be smaller than the number of the second chip pads 35. The number of the third chip pads 45 arranged may be equal to the number of the second channel pads 12.

The fourth semiconductor chip 50 may include fourth chip pads 55, which are disposed adjacent to the second side surface 2S. In some embodiments, a plurality of fourth chip pads 55 may be spaced apart from each other in the second direction D2. In the case where the fourth semiconductor chip 50 is the uppermost semiconductor chip, the fourth semiconductor chip 50 may not have an opened pad, which is adjacent to the first side surface 1S.

The third chip pads 45 and the second channel pad 12 may be connected to each other using the second channel wire 212. The second chip pads 35 and the third chip pads 45 may be connected to each other using the power-ground wire 33. The third chip pads 45 and the fourth chip pads 55 may be connected to each other using the connection wire 32.

The first power-ground pad 46 may be closer to the second chip pad 35 than the third chip pad 45. The fourth semiconductor chip 50 and the second semiconductor chip 30 may be disposed such that they are rotated 180 degrees relative to each other, when viewed in a plan view (e.g., the second chip pad 35 of the second semiconductor chip 30 may be closer to the side surface 1S of the substrate 10 than the side surface 2S of the substrate 10 in the first direction D1, and the chip pads of the fourth semiconductor chip 50 may be closer to the side surface 2S of the substrate 10 than the side surface 1S of the substrate 10 in the first direction D1).

The first semiconductor chip 20 and the second semiconductor chip 30 may be electrically connected to the first channel pad 11, and the third semiconductor chip 40 and the fourth semiconductor chip 50 may be electrically connected to the second channel pad 12. The second semiconductor chip 30 and the third semiconductor chip 40 may be electrically connected to each other through the power-ground wire 33.

The electric power supplied to the second semiconductor chip 30 may be partially transferred to the third semiconductor chip 40 through the power-ground wire 33. In this case, it may be possible to prevent or inhibit a semiconductor chip at a higher level from experiencing a power shortage issue and thereby to improve the electrical characteristics of the semiconductor package.

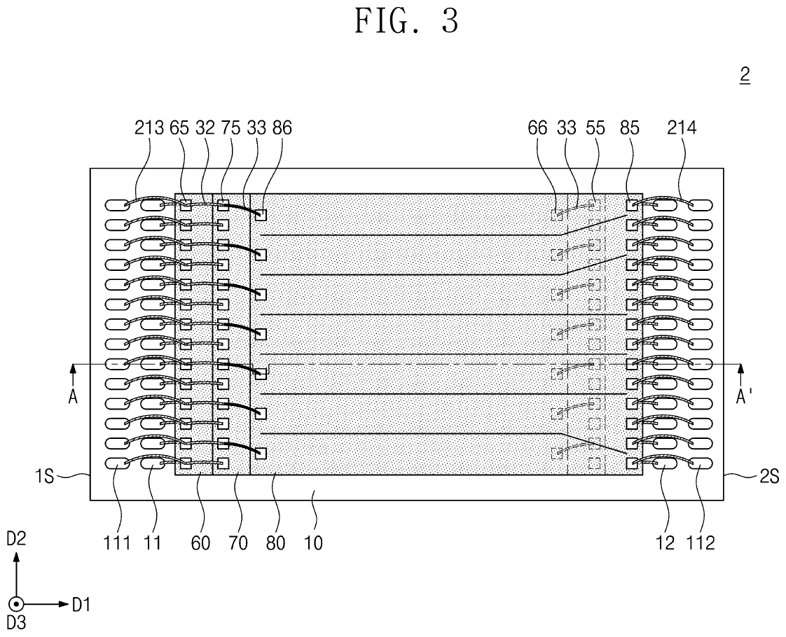

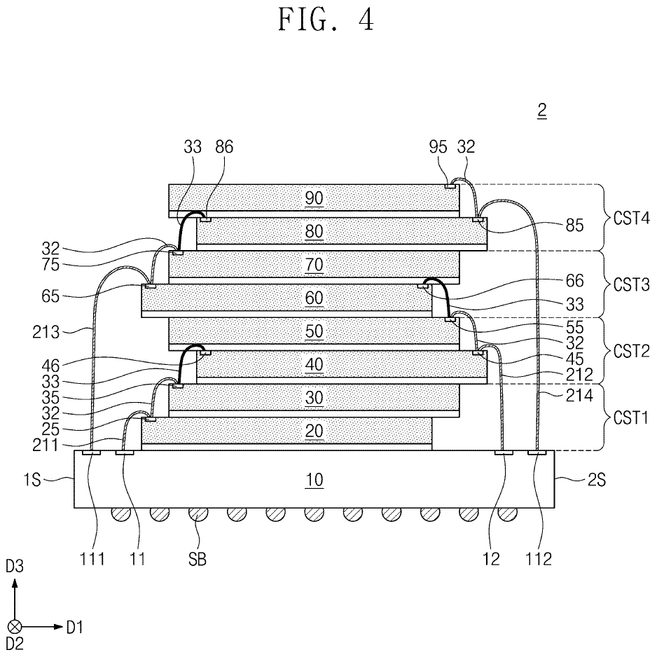

FIG. 3 is a plan view illustrating a semiconductor device according to some embodiments of the present disclosure. FIG. 4 is a sectional view taken along a line A-A′ of FIG. 3 to illustrate a semiconductor device according to some embodiments of the present disclosure. For concise description, an element described above may be identified by the same reference number without repeating an overlapping description thereof.

Referring to FIGS. 3 and 4, a semiconductor device 2 may be provided. In the semiconductor device 2, the substrate 10 may include a third channel pad 111, which is adjacent to the first side surface 1S and is spaced apart from the first channel pad 11. The substrate 10 may include a fourth channel pad 112, which is adjacent to the second side surface 2S and is spaced apart from the second channel pad 12.

A third chip structure CST3 may be disposed on the second chip structure CST2, and a fourth chip structure CST4 may be disposed on the third chip structure CST3.

The third chip structure CST3 may be disposed such that it is rotated 180 degrees relative to the second chip structure CST2, when viewed in a plan view (e.g., the chip pads of the third chip structure CST3 may be closer to the side surface 1S of the substrate 10 than the side surface 2S of the substrate 10 in the first direction D1, and the chip pads of the second chip structure CST2 may be closer to the side surface 2S of the substrate 10 than the side surface 1S of the substrate 10 in the first direction D1). The fourth chip structure CST4 may be disposed such that it is rotated 180 degrees relative to the third chip structure CST3, when viewed in a plan view (e.g., the chip pads of the third chip structure CST3 may be closer to the side surface 1S of the substrate 10 than the side surface 2S of the substrate 10 in the first direction D1, and the chip pads of the fourth chip structure CST4 may be closer to the side surface 2S of the substrate 10 than the side surface 1S of the substrate 10 in the first direction D1).

The third chip structure CST3 may include a fifth semiconductor chip 60 in contact with the fourth semiconductor chip 50 and a sixth semiconductor chip 70 on the fifth semiconductor chip 60. The third chip structure CST3 may include a third channel wire 213 connecting the fifth semiconductor chip 60 to the third channel pad 111, the connection wire 32 connecting the sixth semiconductor chip 70 to the fifth semiconductor chip 60, and the power-ground wire 33 connecting the fourth semiconductor chip 50 to the fifth semiconductor chip 60.

The fourth semiconductor chip 50 and the sixth semiconductor chip 70 may be disposed such that they are rotated 180 degrees relative to each other, when viewed in a plan view (e.g., the chip pads of the sixth semiconductor chip 70 may be closer to the side surface 1S of the substrate 10 than the side surface 2S of the substrate 10 in the first direction D1, and the chip pads of the fourth semiconductor chip 50 may be closer to the side surface 2S of the substrate 10 than the side surface 1S of the substrate 10 in the first direction D1). The fifth semiconductor chip 60 and the third semiconductor chip 40 may be disposed such that they are rotated 180 degrees relative to each other, when viewed in a plan view (e.g., the chip pads of the third semiconductor chip 40 may be closer to the side surface 1S of the substrate 10 than the side surface 2S of the substrate 10 in the first direction D1, and the chip pads of the fifth semiconductor chip 60 may be closer to the side surface 2S of the substrate 10 than the side surface 1S of the substrate 10 in the first direction D1).

The fifth semiconductor chip 60 may include a fifth chip pad 65, which is disposed adjacent to the first side surface 1S, and a second power-ground pad 66, which is disposed adjacent to the second side surface 2S. The fifth chip pad 65 and the second power-ground pad 66 may be spaced apart from each other in the first direction D1. A plurality of second power-ground pads 66 may be arranged in the second direction D2, and a plurality of fifth chip pads 65 may be arranged in the second direction D2. The number of the second power-ground pads 66 may be smaller than the number of the fourth chip pads 55. The first chip pad 25 and the fifth chip pad 65 may at least partially vertically (e.g., in the third direction D3) overlap each other.

The sixth semiconductor chip 70 may include a sixth chip pad 75, which is disposed adjacent to the first side surface 1S. The sixth chip pads 75 may be arranged in the second direction D2.

The sixth chip pad 75 and the fifth chip pad 65 may be connected to each other through the connection wire 32. The fifth chip pad 65 may be connected to the third channel pad 111 through the third channel wire 213. The second power-ground pad 66 and the fourth chip pad 55 may be connected to each other through the power-ground wire 33. The fourth semiconductor chip 50 and the fifth semiconductor chip 60 may be connected to each other through the power-ground wire 33.

The sixth semiconductor chip 70 may include the sixth chip pad 75 disposed adjacent to the first side surface 1S. In some embodiments, a plurality of sixth chip pads 75 may be arranged in the second direction D2. The sixth chip pad 75 and the second chip pad 35 may at least partially vertically (e.g., in the third direction D3) overlap each other.

The sixth chip pad 75 and the fifth chip pad 65 may be connected to each other through the connection wire 32.

The fourth chip structure CST4 may include a seventh semiconductor chip 80 in contact with the sixth semiconductor chip 70 and an eighth semiconductor chip 90 on the seventh semiconductor chip 80. The fourth chip structure CST4 may include a fourth channel wire 214 connecting the seventh semiconductor chip 80 to the fourth channel pad 112, the connection wire 32 connecting the eighth semiconductor chip 90 to the seventh semiconductor chip 80, and the power-ground wire 33 connecting the sixth semiconductor chip 70 to the seventh semiconductor chip 80.

The eighth semiconductor chip 90 and the sixth semiconductor chip 70 may be disposed such that they are rotated 180 degrees relative to each other, when viewed in a plan view (e.g., the chip pads of the sixth semiconductor chip 70 may be closer to the side surface 1S of the substrate 10 than the side surface 2S of the substrate 10 in the first direction D1, and the chip pads of the eighth semiconductor chip 90 may be closer to the side surface 2S of the substrate 10 than the side surface 1S of the substrate 10 in the first direction D1). The fifth semiconductor chip 60 and the seventh semiconductor chip 80 may be disposed such that they are rotated 180 degrees relative to each other, when viewed in a plan view (e.g., the chip pads of the seventh semiconductor chip 80 may be closer to the side surface 1S of the substrate 10 than the side surface 2S of the substrate 10 in the first direction D1, and the chip pads of the fifth semiconductor chip 60 may be closer to the side surface 2S of the substrate 10 than the side surface 1S of the substrate 10 in the first direction D1).

The seventh semiconductor chip 80 may include a seventh chip pad 85, which is disposed adjacent to the second side surface 2S, and a third power-ground pad 86, which is disposed adjacent to the first side surface 1S. The seventh chip pad 85 and the third power-ground pad 86 may be spaced apart from each other in the first direction D1. A plurality of the third power-ground pads 86 may be arranged in the second direction D2, and a plurality of seventh chip pads 85 may be arranged in the second direction D2. The number of the third power-ground pads 86 may be smaller than the number of the sixth chip pads 75. The second chip pad 35 and the sixth chip pad 75 may at least partially vertically (e.g., in the third direction D3) overlap each other.

The eighth semiconductor chip 90 may include an eighth chip pad 95 disposed adjacent to the second side surface 2S. In some embodiments, a plurality of eighth chip pads 95 may be arranged in the second direction D2. The eighth chip pad 95 may at least partially vertically (e.g., in the third direction D3) overlap the fourth chip pad 55.

The eighth chip pad 95 and the seventh chip pad 85 may be connected to each other through the connection wire 32. The seventh chip pad 85 may be connected to the fourth channel pad 112 through the fourth channel wire 214. The third power-ground pad 86 and the sixth chip pad 75 may be connected to each other through the power-ground wire 33. The sixth semiconductor chip 70 and the seventh semiconductor chip 80 may be connected to each other through the power-ground wire 33.

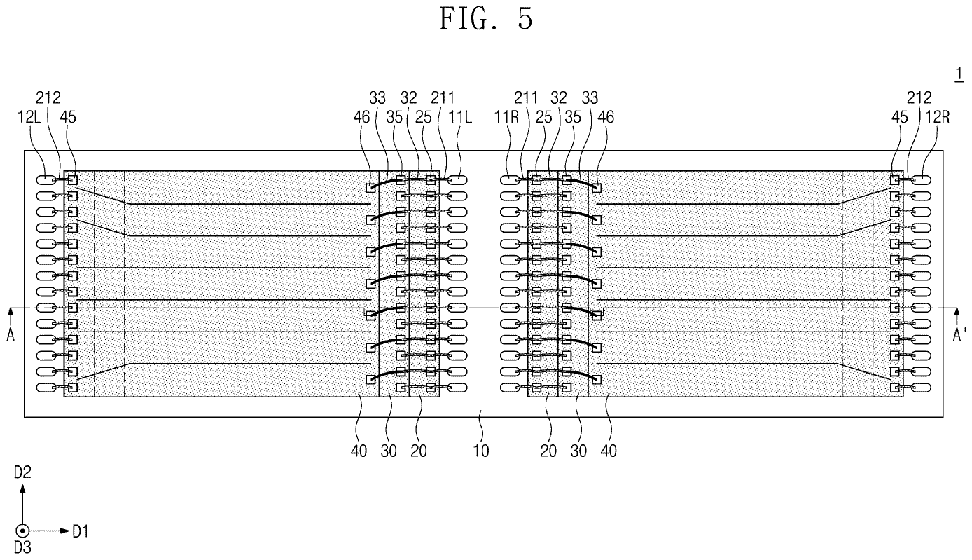

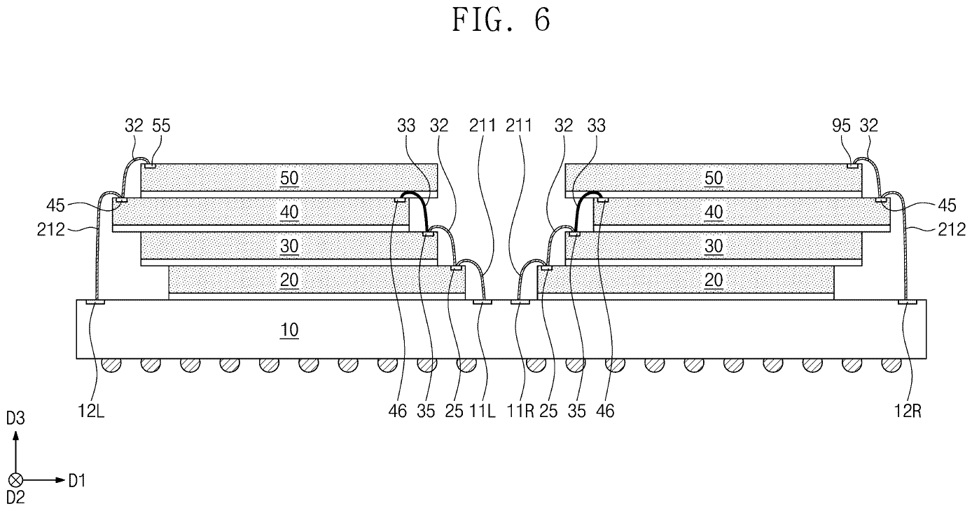

FIG. 5 is a plan view illustrating a semiconductor device according to some embodiments of the present disclosure. FIG. 6 is a sectional view taken along a line A-A′ of FIG. 5 to illustrate a semiconductor device according to some embodiments of the present disclosure. For concise description, a previously described element may be identified by the same reference number without repeating an overlapping description thereof.

Referring to FIGS. 5 and 6, a first chip structure set CSS1 and a second chip structure set CSS2, which are separated to face each other, may be disposed on the substrate 10.

The substrate 10 may include a first channel 11L and a second channel 12L, which are spaced apart from each other. The substrate 10 may include a third channel 11R, which is spaced apart from the first channel 11L, and a fourth channel 12R, which is spaced apart from the first channel 11R.

The first chip structure set CSS1 may be connected to the first channel 11L and the second channel 12L of the substrate 10, and the second chip structure set CSS2 may be connected to the third channel 11R and the fourth channel 12R.

The first chip structure set CSS1 and the second chip structure set CSS2 may be similar to those in the semiconductor device 1 of FIG. 1.

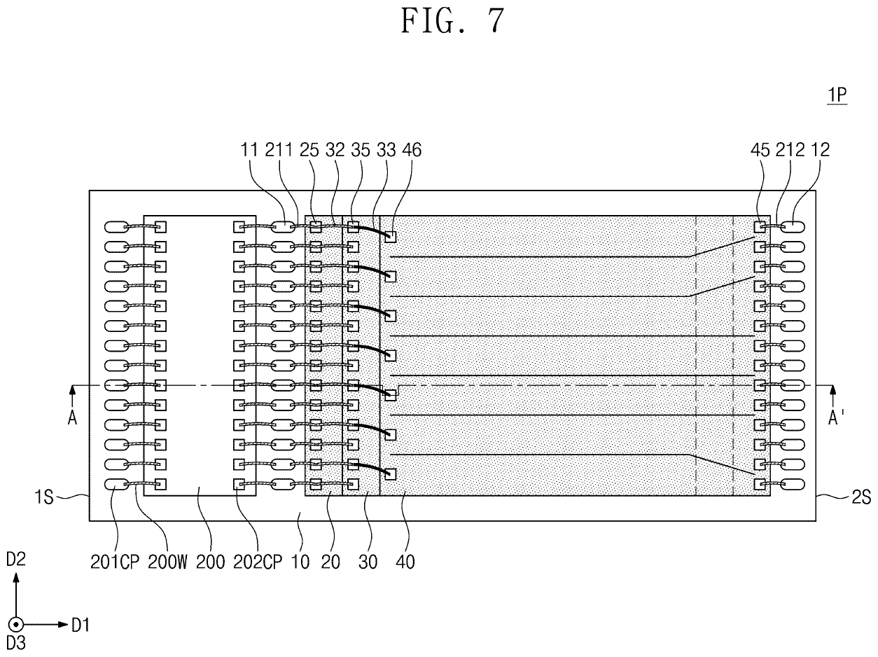

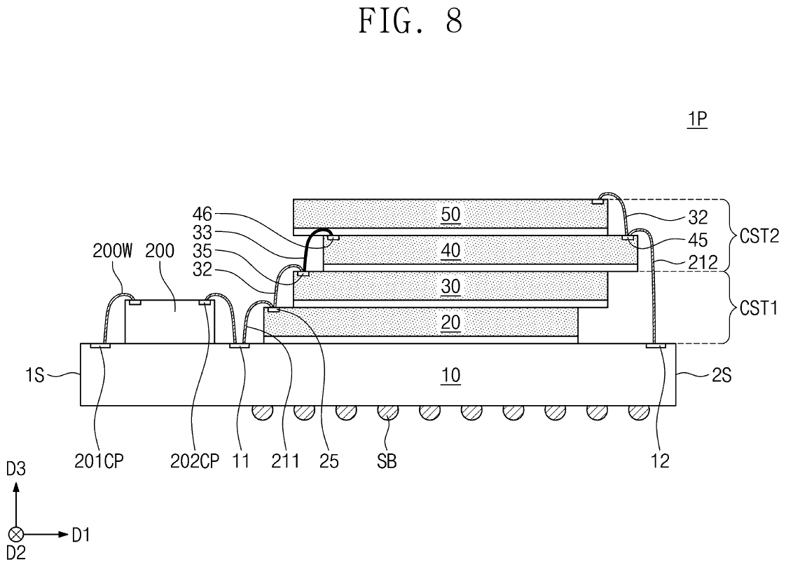

FIG. 7 is a plan view illustrating a semiconductor device according to some embodiments of the present disclosure. FIG. 8 is a sectional view taken along a line A-A′ of FIG. 7 to illustrate a semiconductor device according to some embodiments of the present disclosure. For concise description, a previously described element may be identified by the same reference number without repeating an overlapping description thereof.

Referring to FIGS. 7 and 8, a semiconductor device 1P may be provided. The first and second chip structures CST1 and CST2 of FIG. 1 and a controller chip 200 may be provided on the substrate 10. The first and second chip structures CST1 and CST2 may be similar to those of the semiconductor device 1 described with reference to FIG. 1.

The controller chip 200 may be disposed adjacent to the first side surface 1S of the substrate 10. In this case, the first and second chip structures CST1 and CST2 may be disposed adjacent to the second side surface 2S of the substrate 10.

The controller chip 200 may include chip pads 202CP, which are arranged in an edge portion of the controller chip 200. The chip pads 202CP of the controller chip 200 may be arranged to be spaced apart from each other in the second direction D2. Control signals or data signals may be input and output to and from some of the chip pads 202CP of the controller chip 200, and a power or ground signal may be input to at least one of the chip pads 202CP of the controller chip 200.

The controller chip 200 may include a central processing unit (CPU), an internal memory, a buffer memory control unit, a host interface, and/or a FLASH interface.

A buffer memory chip may be provided in place of the controller chip 200, and the buffer memory chip may be a volatile memory chip. For example, the buffer memory chip may be a dynamic random access memory (DRAM) chip.

A controller pad 201CP may be disposed between the controller chip 200 and the first side surface 1S. Multiple controller pads 201CP may be arranged to be spaced apart from each other in the second direction D2. The substrate 10 and the controller chip 200 may be connected to each other through the controller pad 201CP.

A controller wire 200W may be provided. The controller wire 200W may connect the chip pads 202CP on the controller chip 200 to the first channel pad 11. The controller wire 200W may connect the chip pads 202CP on the controller chip 200 to the controller pad 201CP.

In a semiconductor package according to some embodiments of the present disclosure, signal pads of a lower chip stack may be connected to a package substrate through lower channel wires, and signal pads of an upper chip stack may be connected to the package substrate through upper channel wires. Chips, which are connected to the package substrate through different channel wires, may be connected to each other through connection wires. Thus, power of a lower chip may be provided to an upper chip, and the electrical characteristics of the semiconductor package may be improved.

While example embodiments of the inventive concept have been particularly shown and described, it will be understood by one of ordinary skill in the art that variations in form and detail may be made therein without departing from the scope of the attached claims.

What is claimed is:

1. A semiconductor package, comprising:
a substrate that comprises a first channel pad and a second channel pad that are spaced apart from each other in a first direction and a first side surface and a second side surface that are opposite to each other;
a first semiconductor chip that is on the substrate and comprises a first chip pad;
a second semiconductor chip that is on the first semiconductor chip and comprises a second chip pad;
a third semiconductor chip that is on the second semiconductor chip and comprises a third chip pad and a first power-ground pad that are spaced apart from each other in the first direction;
a first channel wire that electrically connects the first chip pad to the first channel pad;
a first connection wire that electrically connects the first chip pad to the second chip pad;
a first power-ground wire that electrically connects the second chip pad to the first power-ground pad; and
a second channel wire that electrically connects the third chip pad to the second channel pad,
wherein the first power-ground pad is closer to the second chip pad than to the third chip pad in the first direction and is configured to receive one of a power signal or a ground signal,
wherein the second semiconductor chip is electrically connected to the first channel pad,
wherein the third semiconductor chip is electrically connected to the second channel pad.

2. The semiconductor package of claim 1, wherein the first channel pad, the first chip pad, the second chip pad, and the first power-ground pad are closer to the first side surface than to the second side surface in the first direction, and wherein the third chip pad is closer to the second side surface than to the first side surface in the first direction.

3. The semiconductor package of claim 1, wherein the first semiconductor chip and the third semiconductor chip are electrically connected to different channel pads.

4. The semiconductor package of claim 1, wherein the second semiconductor chip and the third semiconductor chip are electrically connected to each other through the first power-ground wire.

5. The semiconductor package of claim 1, further comprising:
a fourth semiconductor chip on the third semiconductor chip; and
a fifth semiconductor chip on the fourth semiconductor chip,
wherein a fourth chip pad of the fourth semiconductor chip is closer to the second side surface of the substrate than the first side surface of the substrate in the first direction, and
wherein a fifth chip pad of the fifth semiconductor chip is closer to the first side surface of the substrate than the second side surface of the substrate in the first direction.

6. The semiconductor package of claim 5,
wherein the fifth semiconductor chip comprises a second power-ground pad adjacent to the second side surface, and
wherein the fifth chip pad at least partially overlaps the first chip pad in a second direction that is perpendicular to an upper surface of the substrate.

7. The semiconductor package of claim 6, further comprising:
a second connection wire that electrically connects the fourth chip pad to the third chip pad; and
a second power-ground wire that electrically connects the fourth chip pad to the second power-ground pad.

8. The semiconductor package of claim 6, further comprising a third channel connection wire adjacent to the first side surface of the substrate,
wherein the substrate further comprises a third channel pad that is spaced apart from the first channel pad in the first direction, and
wherein the fifth chip pad and the third channel pad are electrically connected to each other through the third channel connection wire.

9. A semiconductor package, comprising:
a substrate comprising a first side surface and a second side surface that are opposite to each other, the substrate comprising a first channel pad adjacent to the first side surface, a second channel pad adjacent to the second side surface, and a third channel pad adjacent to the first channel pad;
a first chip structure on the substrate;
a second chip structure on the first chip structure comprising a second set of chip pads adjacent to the first side surface; and
a third chip structure that is on the second chip structure and comprises a third set of chip pads that is closer to the second side surface than the second set of chip pads in a first direction that is parallel to an upper surface of the substrate,
wherein the first chip structure is electrically connected to the first channel pad,
the second chip structure is electrically connected to the second channel pad,
the second chip structure comprises a first power-ground wire adjacent to the first side surface,
the third chip structure comprises a second power-ground wire adjacent to the second side surface,
the first power-ground wire electrically connects the first chip structure to the second chip structure, and
the second power-ground wire electrically connects the second chip structure to the third chip structure.

10. The semiconductor package of claim 9, wherein the first chip structure comprises:
a first semiconductor chip comprising a first chip pad electrically connected to the first channel pad, and
a second semiconductor chip comprising a second chip pad electrically connected to the first chip pad,
wherein the first channel pad and the first chip pad are electrically connected to each other by a first channel wire.

11. The semiconductor package of claim 10, wherein the second set of chip pads comprise a third chip pad that is adjacent to the second side surface and a fourth chip pad, and wherein the second chip structure comprises:
a third semiconductor chip comprising a first power-ground pad electrically connected to the second chip pad and the third chip pad, and
a fourth semiconductor chip comprising the fourth chip pad electrically connected to the third chip pad,
wherein the first power-ground pad and the second chip pad are electrically connected to each other by the first power-ground wire.

12. The semiconductor package of claim 9, further comprising a fourth chip structure on the third chip structure,
wherein the fourth chip structure comprises a third power-ground wire,
wherein the first power-ground wire and the third power-ground wire are adjacent to the first side surface, and
wherein the second power-ground wire is adjacent to the second side surface.

13. The semiconductor package of claim 9, wherein the first chip structure comprises:
a first semiconductor chip comprising a first chip pad electrically connected to the first channel pad, and
a second semiconductor chip comprising a second chip pad electrically connected to the first chip pad,
wherein the second set of chip pads comprise a third chip pad that is adjacent to the second side surface and a fourth chip pad,
wherein the second chip structure comprises:
a third semiconductor chip comprising a first power-ground pad electrically connected to the second chip pad and the third chip pad, and
a fourth semiconductor chip comprising the fourth chip pad electrically connected to the third chip pad,
wherein the third chip structure comprises a fifth semiconductor chip comprising a second power-ground pad electrically connected to the fourth chip pad and a fifth chip pad adjacent to the first side surface,
wherein the third channel pad is adjacent to the first side surface, and
the third channel pad and the fifth chip pad are electrically connected to each other by a third channel wire.

14. The semiconductor package of claim 9, further comprising a fourth chip structure that is on the third chip structure and comprises a fourth set of chip pads that is closer to the first side surface than the third set of chip pads in the first direction.

15. The semiconductor package of claim 14, wherein the substrate further comprises a fourth channel pad adjacent to the second channel pad,
wherein each of the first chip structure, the second chip structure, the third chip structure, and the fourth chip structure comprises a plurality of semiconductor chips,
wherein a lowermost semiconductor chip of the plurality of semiconductor chips of each of the first chip structure, the second chip structure, the third chip structure, and the fourth chip structure is electrically connected to a corresponding one of the first channel pad, the second channel pad, the third channel pad, or the fourth channel pad.

16. The semiconductor package of claim 9, wherein the substrate further comprises a fourth channel pad adjacent to the second channel pad,
wherein the semiconductor package further comprises a fourth chip structure on the third chip structure,
wherein the third chip structure is electrically connected to the third channel pad, and
wherein the fourth chip structure is electrically connected to the fourth channel pad.

17. A semiconductor package, comprising:
a substrate comprising a first side surface and a second side surface that are opposite to each other, the substrate comprising a first channel pad in a first direction that is parallel to an upper surface of the substrate, a second channel pad spaced apart from the first channel pad in the first direction, a third channel pad adjacent to the first channel pad, and a fourth channel pad adjacent to the second channel pad;
a first semiconductor chip that is on the substrate and comprises a first chip pad;
a second semiconductor chip that is on the first semiconductor chip and comprises a second chip pad;
a third semiconductor chip that is on the second semiconductor chip and comprises a third chip pad and a first power-ground pad spaced apart from each other in the first direction;
a fourth semiconductor chip that is on the third semiconductor chip and comprises a fourth chip pad;
a fifth semiconductor chip that is on the fourth semiconductor chip and comprises a fifth chip pad and a second power-ground pad spaced apart from each other in the first direction;
a first channel wire electrically connecting the first chip pad to the first channel pad;
a connection wire electrically connecting the first chip pad to the second chip pad;
a power-ground wire electrically connecting the second chip pad to the first power-ground pad and electrically connecting the fourth chip pad to the second power-ground pad;
a second channel wire electrically connecting the third chip pad to the second channel pad; and
a third channel wire electrically connecting the fifth chip pad to the third channel pad,
wherein the second semiconductor chip is electrically connected to the first channel pad,
wherein the third semiconductor chip is electrically connected to the second channel pad, and
wherein the second semiconductor chip and the third semiconductor chip are electrically connected to each other through the power-ground wire.

18. The semiconductor package of claim 17, further comprising:
a sixth semiconductor chip that comprises a sixth chip pad and is on the fifth semiconductor chip;
a seventh semiconductor chip that is on the sixth semiconductor chip and comprises a seventh chip pad and a third power-ground pad spaced apart from each other in the first direction; and
a fourth channel wire electrically connecting the seventh chip pad to the fourth channel pad.

19. The semiconductor package of claim 18, wherein the first power-ground pad is adjacent to the first side surface, and
wherein the second power-ground pad is adjacent to the second side surface.

20. The semiconductor package of claim 17, wherein the fifth chip pad is closer to the first side surface of the substrate than the second side surface of the substrate in the first direction, and wherein the third chip pad is closer to the second side surface of the substrate than the first side surface of the substrate in the first direction.
